(19) United States
(12) Patent Application Publication
(10) Pub. No.: US 2015/0115358 A1
(43) Pub. Date: Apr. 30, 2015

(54) Semiconductor Device

(71) Applicant: Infineon Technologies Austria AG, Villach (AT)

(72) Inventors: Anton Mauder, Kolbermoor (DE); Winfried Kaindl, Unterhaching (DE); Uwe Wahl, Muenchen (DE)

(21) Appl. No.: 14/525,312

(22) Filed: Oct. 28, 2014

(30) Foreign Application Priority Data
Oct. 30, 2013 (CN) 201320675405.6

(51) Int. Cl. H01L 27/088; H01L 29/423; H01L 23/522; H01L 23/528; H01L 23/532; H01L 29/06; H01L 29/49

(52) U.S. Cl. CPC H01L 27/088; H01L 29/0634; H01L 29/0696; H01L 29/4236; H01L 29/4916; H01L 23/528; H01L 23/53271; H01L 23/5221
USPC 257/334; 257/390

(57) ABSTRACT

The present disclosure provides a semiconductor device, including a compensation area that includes p-regions and n-regions, a plurality of transistor cells including gate electrodes on the compensation area, and one or more interconnections for electrically connecting gate electrodes. The gate electrodes may have a width smaller than ½ of a pitch of the cells.

### FIELD

This disclosure relates to a semiconductor device, in particular, to a super-junction device.

### BACKGROUND

For the fast switching of super-junction transistors it is desirable to have a low gate charge. This reduces switching losses, driving losses and facilitates the driver concept. For instance, boosters following the driver to supply high peak currents to the gate of the switching transistors can be omitted. Thus cost for development, board space, cooling efforts and additional devices can be saved.

On the other hand, a reduced gate charge of the super-junction transistor reduces delay time for turning-on and turning-off of the transistor. Since delay times reduce the phase margin in control loops, a super-junction transistor with lower delay time improves the stability of control loops.

It is obvious that a small gate charge is beneficial for super-junction transistors.

The gate charge of a super-junction transistor is dominated by the gate-source and by the gate-drain capacitance. Thus the gate charge may be reduced by reducing the overlapping areas between source and gate and gate and drain respectively. This goal can be reached by minimizing the area of the gate electrode of the super-junction transistor.

Major drawback of a reduced gate electrode area is an increased series resistance of the gate electrode due to the smaller cross sectional area of the gate electrode. Thus switching of the super-junction transistor becomes inhomogeneous. For instance, a part of the chip area adjacent to the gate connection of the super-junction transistor already responds to a change in the gate voltage while other parts of the chip area farther from the gate connection (gate pad) still remain on their previous state. Such a delayed and inhomogeneous switching may lead to increased switching losses and to instable switching or even to oscillations.

However, the cross section of the gate electrode may not be sufficiently increased by increasing the thickness of the electrode because this will lead to an increased topology on the super-junction device during manufacturing. Here a maximum thickness of the electrode may not be exceeded to maintain manufacturability of the super-junction transistor.

There is the need for a structure enabling a small gate charge of a super-junction transistor by providing a small area of the gate electrode and a small internal gate distribution resistor at the same time.

### SUMMARY

According to one embodiment of the disclosure, a semiconductor device is provided, comprising a compensation area which comprises p-regions and n-regions, a plurality of transistor cells comprising gate electrodes on the compensation area, and one or more interconnections for electrically connecting gate electrode. In one embodiment the gate electrodes having a width smaller than ½ of a pitch of the cells.

In one embodiment the width of the gate electrodes is smaller than ⅓ of the pitch of the cells.

In one embodiment the gate electrodes comprise polycrystalline silicon.

In one embodiment the interconnections comprise polycrystalline silicon.

In one embodiment at least one of the interconnections connects only two adjacent gate electrodes.

In one embodiment at least one of the interconnections connects more than two gate electrodes.

In one embodiment the semiconductor device comprises at least a first wiring layer and a second wiring layer.

In one embodiment the first wiring layer comprises the interconnections and the gate electrodes.

In one embodiment the second wiring layer comprises a source metallization and at least one of a gate runner and a gate finger.

In one embodiment the at least one of the gate runner and the gate finger is electrically connected to at least one of the interconnections via gate contacts.

In one embodiment the transistor cells comprise further source and body regions and the source metallization is electrically connected to the source and body regions by plugs/source contact holes.

In one embodiment the transistor cells are stripe-shaped.

In one embodiment the interconnections are located at the end of the transistor cells.

In one embodiment the gate electrodes are connected to a gate ring at the end of the transistor cells or to a gate finger at intersections of the transistor cells.

In one embodiment the interconnections are arranged in regular distances in an active area.

In one embodiment the gate electrodes are parallel to each other.

In one embodiment the gate electrodes have a planar structure.

In one embodiment the gate electrodes are located at least partially in trenches.

In one embodiment the interconnections are implemented as bridge.

In one embodiment the interconnections are located at least partially in trenches.

In one embodiment the semiconductor device comprises further a substrate and a buffer layer between the substrate and the compensation area.

In one embodiment the buffer layer has a doping concentration which is larger in a lower part than in an upper part.

In one embodiment the n-regions have a doping concentration which is larger in a lower part than in an upper part.

In one embodiment the transistor cells comprise further body regions below the interconnections.

In one embodiment the semiconductor device is a super-junction device.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates schematic cross-sectional views of three not limiting examples for a part of a super-junction transistor.

FIG. 2 is top views of a super-junction transistor, illustrating a plurality of wiring layers.

FIG. 3 is cross section through a super-junction transistor parallel to the gate electrode, where body regions (here shown as under-diffusion of the Si-connections) form a shield between poly-gate and drain.

FIG. 4 is top view and cross section through a super-junction transistor having a trench gate structure according to an embodiment.

### DETAILED DESCRIPTION

In the following detailed description, reference is made to the accompanying drawings, which form a part hereof, and in which is shown by way of illustration specific embodiments in which the disclosure may be practiced. In this regard, directional terminology, such as “top,” “bottom,” “front,” “back,” “leading,” “trailing,” etc., is used with reference to the orientation of the figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present disclosure. The following detailed description, therefore, is not to be taken in a limiting sense, and the scope of the present disclosure is defined by the appended claims.

It is to be understood that the features of the various exemplary embodiments described herein may be combined with each other, unless specifically noted otherwise.

As employed in this specification, the terms “coupled” and/or “electrically coupled” are not meant to mean that the elements must be directly coupled together; intervening elements may be provided between the “coupled” or “electrically coupled” elements.

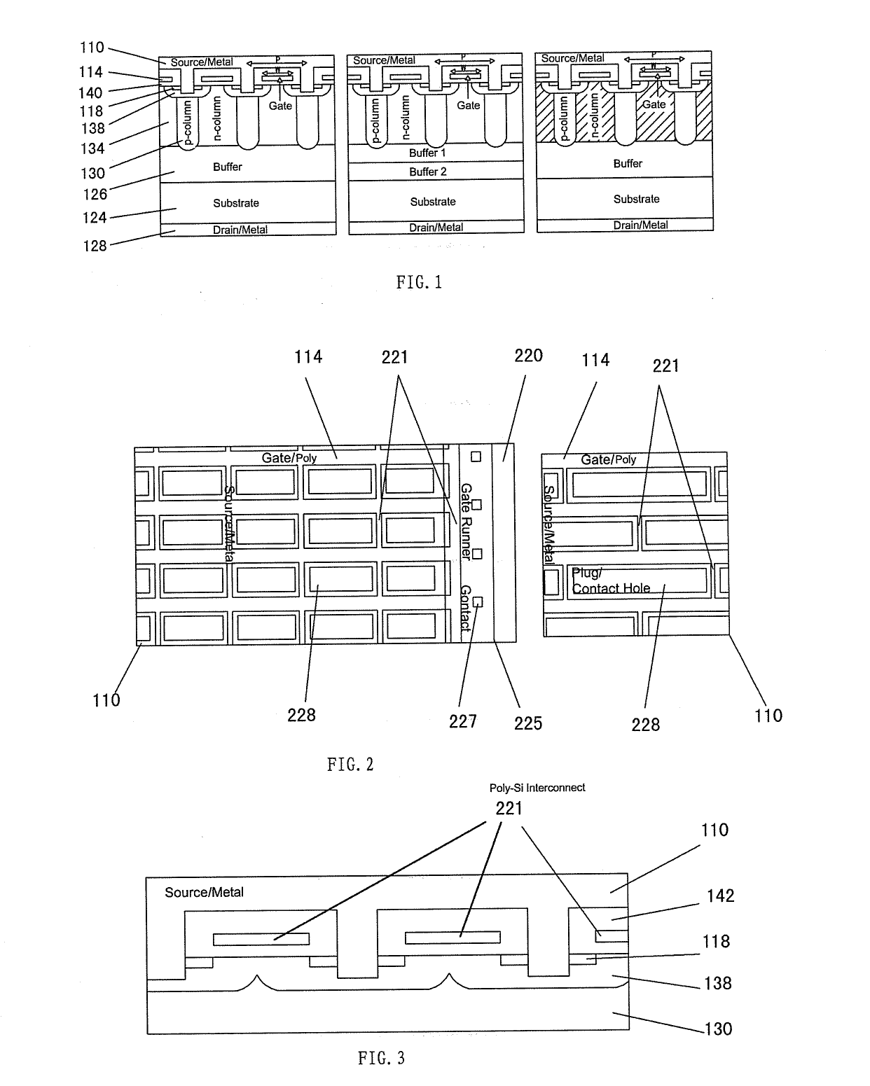

FIG. 1 illustrates schematic cross-sectional views of three not limiting examples for super-junction transistors. Different possibilities for realizing a compensation area and an optional buffer region are shown. These examples are not limiting and the different versions may be combined in any manner. For simplicity, only cross sections of a part of the active area, i. e. the area carrying the vertical load current, are shown. Parts of the transistors like an edge termination system, a dicing area or the gate connects are not explicitly shown in FIG. 1. The devices shown have a semiconductor body with a compensation area comprising p-regions (p-columns) 130 and n-regions (n-columns) 134 where the compensation, i. e. the difference in the doping between p- and n-columns may be either homogeneous or variable in the vertical direction.

The compensation region is connected to a MOS transistor cell comprising a source 118, a body region 138 and a controlling gate 114. In the examples shown the gate is built as a planar gate electrode situated on top of the semiconductor body. However, the gate could also be realized in a trench etched into the semiconductor body.

An insulating structure 140, such as oxide, electrically isolates the gate 114 from the body region 138, the source 118, the n-regions (n-columns) 134 and a metallization layer 110. And a part of the insulating structure 140 may act as gate insulating layer.

The drain 128 of the transistor is connected to a highly doped substrate 124. Between the substrate and the compensation area an optional buffer layer 126 may be located. The buffer layer has the same conductivity type as the substrate but a lower doping. The doping of the buffer layer may vary in the vertical direction. As an example the cross section shown in the middle of FIG. 1 depicts step wise varying doping levels in the buffer layer. For example, the buffer layer may include a plurality of sublayers, such as a first sublayer (buffer 1) and a second sublayer (buffer 2), and the doping for the second sublayer may be above that of the first sublayer. As an example again, the cross section shown in the right of FIG. 1 depicts the doping for the n-regions (n-columns) 134 increase step-wise and/or gradually in a direction from the insulating structure 140 to the buffer layer 126. According to an embodiment (not shown in FIG. 1) the doping of the n-regions (n-columns) and/or the doping of the p-regions (p-columns) may have one or more local doping maximums and one or more local doping minimums in a direction from the insulating structure 140 to the buffer layer 126.

The source contacts are electrically connected by the metallization layer 110 which builds a common source pad at chip top side. The individual cell gates 114 are connected by poly silicon to build a common gate contact with a metallization at top side. And hence two electrodes with same or different metallizations, one for source and one for gate, are disposed at device top side and are isolated from each other e. g. by Si-oxide or Si-nitride passivation layers or both. The drain contact is build at the device backside and is covered with metallization 128 of super-junction devices.

In one embodiment of super-junction transistors the material of the gate electrode is n-doped polycrystalline silicon due to the suitable work function for n-channel MOSFETs and its manufacturability. However, the series resistance of poly-silicon is limited by the solubility of the doping material (e. g. phosphorous) so for a layer of 500 nm thickness the sheet resistance cannot fall below approximately 10Ω.

Meanwhile, the super-junction transistor having stripe-shaped cells normally has no connections between the substantially parallel electrodes. Therefore the gate potential of the parallel cells of the super-junction transistor may differ due to the internal feedback of the drain, some small (unintended) structural differences between the cells or a temperature gradient in the chip, just to name only a few possibilities. The gate electrodes may be connected only at their ends to a metallic gate runner. A gate runner in this context is a highly conductive line, e. g. made from some metal, which enables a low ohmic connection between the gate electrodes and a gate pad.

The problem with inhomogeneous switching grows with the chip area of super-junction transistors.

The structure disclosed in this invention gains in importance with bigger chip areas of more than 20 mm² or more than 35 mm² or more than 50 mm².

According to one embodiment of the disclosure, for optimum gate charge the width of the gate electrode w as shown in FIG. 1 does not exceed about 50% of the pitch p of the cell. In one embodiment the width of the gate electrode w is smaller than ½ of the pitch p of the cells. In another embodiment the width of the gate electrode is smaller than ⅓ of the pitch p of the cells.

In addition, to provide a homogeneous distribution of the gate voltage and thus a homogeneous switching behavior of the cells an electrical connection between two adjacent gate electrode structures can be used and/or electrical connections between the gate electrode structure and the gate finger can be used.

FIG. 2 is top views of a super-junction transistor, illustrating a plurality of wiring layers. On a semiconductor layer 220 (which comprises for example the transistor cells described above), a first wiring layer is placed which comprises substantially parallel gate electrodes 114 (extending along the horizontal direction), one or more interconnections 221 (extending along the vertical direction) between the substantially parallel electrodes 114. On the first wiring layer, a second wiring layer is placed which comprises a source metallization 110 and at least one of a gate runner 225 and a gate finger. The at least one of the gate runner and the gate finger is connected to the interconnections 221 and/or gate electrodes 114 via gate contacts 227. The source metallization 110 is connected to the source 118 and body region 138 via plugs/source contact holes 228. The interconnections 221 between two adjacent gate electrodes 114 lead to a leveling of the gate electrode potential of the super-junction transistor. In left view of FIG. 2, straight interconnects 221 are shown. In right view of FIG. 2, cascaded interconnects 221 are shown. The interconnections 221 and gate electrodes 114 for example may be formed by polycrystalline silicon.

As shown in FIG. 2, the super-junction transistor may have one or more interconnections 221 between the substantially parallel electrodes 114. These interconnections can be used e. g. for a more homogeneous distribution of the gate potential on the super-junction transistor and thus for a more homogeneous switching behavior of the cells.

Optionally, these interconnections may be at the end of the stripe-shape cells and/or also in regular distances in the active area. At the end of the cell area also a further optional connections from the gate electrode(s) to a surrounding gate ring can be provided. Alternatively or additionally, at least a gate finger can be provided intersecting the cells in the active area. In one embodiment the gate electrodes are connected to the at least a gate finger at intersections of the transistor cells. At these intersections the source electrodes and the contact holes of the source contact may be omitted (not shown in FIG. 2).

Of course, the contact holes between source and body connection and the source metallization must not be continuous but intermittent at an interconnect 221 as shown in FIG. 2 to prevent an electrical short circuit between gate and source.

However, to maintain the target of low gate charge, the coupling between the drain electrode and the additional interconnects should be minimized. In one embodiment, the p-body regions 138 of the super-junction transistor should be located underneath the additional interconnects 221 surrounding by an insulating structure 142, as shown in FIG. 3. The body regions 138 then form a shield between the drain and the additional interconnects on gate potential.

According to another embodiment, the source regions 118 next to the poly-Si-connections 221 are not present (e. g. masked implantation) and/or additional p-doping is provided to prevent the development of an additional inversion channel (not shown in FIG. 3).

In the embodiment of FIG. 3 the cross section is made through p-columns 130. Of course in a cross section that is orthogonal compared to the cross section of FIG. 3 the body regions must not overlap to leave a conductive channel. For such a cross section please refer to FIG. 1.

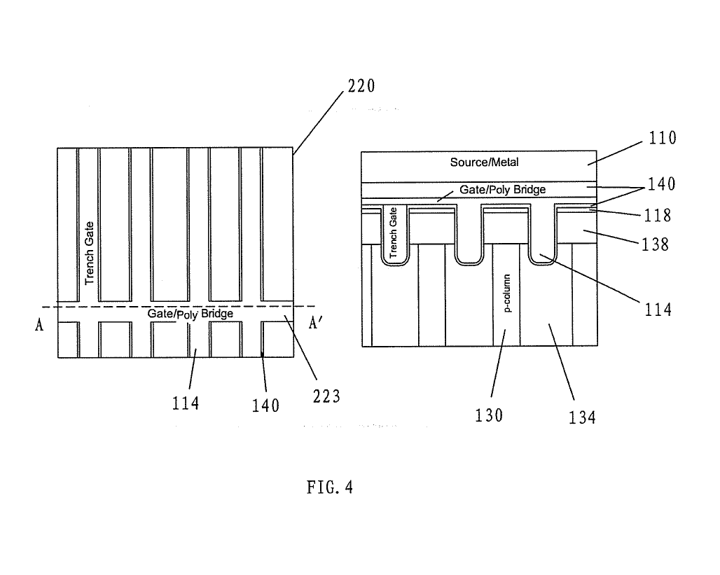

In another embodiment, the super-junction transistor may also be built using a cell structure with the gate electrode in a trench. FIG. 4 shows a top view of a stripe-shaped trench cell structure of a super-junction transistor (left) and the cross section at points A-A′ (right). As shown in FIG. 4, the gate electrodes 114 are at least partially located in trenches

According to an embodiment, the poly bridge 223 connecting adjacent gate electrodes may be realized as a poly silicon line above the semiconductor surface.

According to another embodiment, the poly bridge is implemented in a trench connecting adjacent gate trenches (not shown in FIG. 4).

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A semiconductor device, comprising:
a compensation area which comprises p-regions and n-regions;
a plurality of transistor cells comprising gate electrodes on the compensation area;
one or more interconnections for electrically connecting gate electrodes,
wherein the gate electrodes having a width smaller than ½ of a pitch of the cells.

2. The semiconductor device of claim 1, wherein the width of the gate electrodes is smaller than ⅓ of the pitch of the cells.

3. The semiconductor device of claim 1, wherein the gate electrodes comprise polycrystalline silicon.

4. The semiconductor device of claim 1, wherein the interconnections comprise polycrystalline silicon.

5. The semiconductor device of claim 1, wherein at least one of the interconnections connect only two adjacent gate electrodes.

6. The semiconductor device of claim 1, wherein at least one of the interconnections connect more than two gate electrodes.

7. The semiconductor device of claim 1, wherein the semiconductor device comprising at least a first and second wiring layers.

8. The semiconductor device of claim 7, wherein the first wiring layer comprises the interconnections and the gate electrodes.

9. The semiconductor device of claim 8, wherein the second wiring layer comprises a source metallization and at least one of a gate runner and a gate finger.

10. The semiconductor device of claim 9, wherein the at least one of the gate runner and the gate finger is electrically connected to at least one of the interconnections via gate contacts.

11. The semiconductor device of claim 9, wherein the transistor cells comprises further source and body regions and the source metallization is electrically connected to the source and body regions by plugs/source contact holes.

12. The semiconductor device of claim 1, wherein the transistor cells are stripe-shaped.

13. The semiconductor device of claim 12, wherein the interconnections are located at the end of the transistor cells.

14. The semiconductor device of claim 12, wherein the gate electrodes are connected to a gate ring at the end of the transistor cells or to a gate finger at intersections of the transistor cells.

15. The semiconductor device of claim 1, wherein the interconnections are arranged in regular distances in an active area.

16. The semiconductor device of claim 1, wherein the gate electrodes are parallel to each other.

17. The semiconductor device of claim 1, wherein the gate electrodes have a planar structure.

18. The semiconductor device of claim 1, wherein the gate electrodes are located at least partially in trenches.

19. The semiconductor device of claim 18, wherein the interconnections are implemented as bridge.

20. The semiconductor device of claim 18, wherein the interconnections are located at least partially in trenches.

21. The semiconductor device of claim 1, comprising further a substrate and a buffer layer between the substrate and the compensation area.

22. The semiconductor device of claim 21, wherein the buffer layer having a doping concentration which is larger in a lower part than in an upper part.

23. The semiconductor device of claim 1, wherein the n-regions having a doping concentration which is larger in a lower part than in an upper part.

24. The semiconductor device of claim 1, wherein the transistor cells comprising further body regions below the interconnections.

25. The semiconductor device of claim 1, wherein the semiconductor device is a super-junction device.
